(19) United States
(12) Patent Application Publication
(10) Pub. No.: US 2026/0164696 A1
(43) Pub. Date: Jun. 11, 2026

(54) NITRIDE SEMICONDUCTOR DEVICE

(71) Applicant: Panasonic Holdings Corporation, Osaka (JP)

(72) Inventors: DAISUKE SHIBATA, Kyoto (JP); HIDEYUKI OKITA, Osaka (JP); KEIICHI MATSUNAGA, Toyama (JP); MASAHIRO HIKITA, Hyogo (JP); DAISUKE MASUNAGA, Osaka (JP)

(21) Appl. No.: 19/405,489

(22) Filed: Dec. 2, 2025

(30) Foreign Application Priority Data
Dec. 10, 2024 (JP) 2024-215378

(51) Int. Cl. H10D 30/47; H10D 8/00; H10D 30/66; H10D 62/10; H10D 62/60; H10D 62/824; H10D 84/80

(52) U.S. Cl. CPC H10D 30/475; H10D 30/477; H10D 62/103; H10D 62/124; H10D 62/60; H10D 62/824; H10D 8/411; H10D 30/665; H10D 84/811

(57) ABSTRACT

A nitride semiconductor device includes a first nitride semiconductor layer with an n-type conductivity, a second nitride semiconductor layer with a p-type conductivity, a source electrode in direct contact with the second nitride semiconductor layer and a mesa structure with two or more steps disposed in a termination region between an active region of the nitride semiconductor device and an inactive region surrounding the active region. The mesa structure includes a mesa at a first step in which a lower end of a side wall of the mesa is located in the second nitride semiconductor layer, and each of mesas at a second and subsequent steps in which a lower end of a side wall of the mesa reaches the first nitride semiconductor layer. The mesa at the first step has a depth that is half or more of a film thickness of the second nitride semiconductor layer.

### BACKGROUND

### 1. Technical Field

The present disclosure relates to a nitride semiconductor device.

### 2. Description of the Related Art

Patent Literature (PTL) 1 discloses a semiconductor device including an n-type GaN layer and a p-type GaN layer stacked on the n-type GaN layer. The semiconductor device disclosed in PTL 1 includes a p-type GaN layer thinned in a termination region provided surrounding an element region, and a gradient distribution low-concentration p region having a lower carrier concentration than a periphery is provided in a thinned part of the p-type GaN layer. The gradient distribution low-concentration p region is low in carrier concentration and thin, and thus is likely to be depleted when reverse voltage is applied, thereby contributing to relaxation of electric field concentration.
PTL 1: Japanese U.S. Pat. No. 6,524,950

### SUMMARY

A nitride semiconductor device according to an aspect of the present disclosure includes a first nitride semiconductor layer with an n-type conductivity, a second nitride semiconductor layer with a p-type conductivity disposed above the first nitride semiconductor layer, a source electrode in direct contact with the second nitride semiconductor layer, and a mesa structure with two or more steps disposed in a termination region between an active region of the nitride semiconductor device and an inactive region surrounding the active region. The mesa structure includes a mesa at a first step in which a lower end of a side wall of the mesa is located in the second nitride semiconductor layer, and each of mesas at a second and subsequent steps in which a lower end of a side wall of the mesa reaches the first nitride semiconductor layer. The mesa at the first step has a depth that is half or more of a film thickness of the second nitride semiconductor layer.

### BRIEF DESCRIPTION OF THE DRAWINGS

FIG. 1 is a sectional view of a nitride semiconductor device according to a first exemplary embodiment;

FIG. 2 is an enlarged sectional view of a main part of the nitride semiconductor device according to the first exemplary embodiment;

FIG. 3 is an enlarged sectional view of a main part of a nitride semiconductor device according to a second exemplary embodiment;

FIG. 4 is an enlarged sectional view of a main part of a nitride semiconductor device according to a third exemplary embodiment;

FIG. 5 is a sectional view of a nitride semiconductor device according to a fourth exemplary embodiment;

FIG. 6 is a sectional view of a nitride semiconductor device according to a fifth exemplary embodiment;

FIG. 7 is a sectional view of a nitride semiconductor device according to a sixth exemplary embodiment;

FIG. 8 is a diagram illustrating a relationship between a depth ratio between a mesa at a first step and a mesa at a second step, and electric field intensity;

FIG. 9 is a diagram illustrating a relationship between a taper angle of a side wall of a mesa at a second step and electric field intensity; and

FIG. 10 is a diagram illustrating a relationship between a taper angle of a side wall of a mesa at a second step and electric field intensity.

### DETAILED DESCRIPTIONS

The structure disclosed in PTL 1 is insufficient to improve withstand voltage.

Thus, the present disclosure provides a nitride semiconductor device capable of increasing withstand voltage.

### Underlying Knowledge on the Present Disclosure

The present inventors have found that the conventional semiconductor device described in the section of “Description of the Related Art” has caused a problem below.

The semiconductor device disclosed in PTL 1 includes the gradient distribution low-concentration p region that is formed by implanting ions into the thinned part of the p-type GaN layer. The ion implantation causes the GaN layer to be likely to be damaged, so that withstand voltage may be deteriorated.

In contrast, a nitride semiconductor device according to a first aspect of the present disclosure includes a first nitride semiconductor layer with an n-type conductivity, a second nitride semiconductor layer with a p-type conductivity disposed above the first nitride semiconductor layer, a source electrode in direct contact with the second nitride semiconductor layer, and a mesa structure with two or more steps disposed in a termination region between an active region of the nitride semiconductor device and an inactive region surrounding the active region. The mesa structure includes a mesa at a first step in which a lower end of a side wall of the mesa is located in the second nitride semiconductor layer, and each of mesas at a second and subsequent steps in which a lower end of a side wall of the mesa reaches the first nitride semiconductor layer. The mesa at the first step has a depth that is half or more of a film thickness of the second nitride semiconductor layer.

Consequently, the electric field concentration in the termination region can be further relaxed, so that the withstand voltage of the nitride semiconductor device can be further increased. The withstand voltage can be increased by adjusting a depth of the mesa at the first step, so that regions different in carrier concentration are not required to be formed by ion implantation. Thus, increase in man-hours in a manufacturing method can be suppressed.

A nitride semiconductor device according to a second aspect of the present disclosure is configured such that the mesa at the first step has a depth that is ⅔ or more of the film thickness of the second nitride semiconductor layer in the nitride semiconductor device according to the first aspect.

Consequently, the electric field concentration in the termination region can be further relaxed, so that the withstand voltage of the nitride semiconductor device can be further increased.

A nitride semiconductor device according to a third aspect of the present disclosure is configured such that the second nitride semiconductor layer serves as a current block layer between a source and a drain in the nitride semiconductor device according to the first aspect or the second aspect.

Consequently, the electric field concentration in the termination region can be further relaxed, so that the withstand voltage of the nitride semiconductor device can be further increased.

A nitride semiconductor device according to a fourth aspect of the present disclosure is configured such that the second nitride semiconductor layer has a p-type dopant concentration less than or equal to 5×10¹⁹ cm⁻³ in the nitride semiconductor device according to any one of the first to third aspects.

Consequently, a leak current between the source and the drain can be reduced.

A nitride semiconductor device according to a fifth aspect of the present disclosure is configured such that the mesa at the first step has a shallower depth than the mesas at the second step in the nitride semiconductor device according to any one of the first to fourth aspects.

Consequently, the electric field concentration in the termination region can be further relaxed, so that the withstand voltage of the nitride semiconductor device can be further increased.

A nitride semiconductor device according to a sixth aspect of the present disclosure is configured such that the mesa at the first step includes a bottom surface with a length less than or equal to 10 μm in the nitride semiconductor device according to the first to fifth aspects.

Consequently, the termination region can be reduced in area, so that downsizing of the nitride semiconductor device or increase in area of the active region can be achieved.

A nitride semiconductor device according to a seventh aspect of the present disclosure is configured such that the mesa structure includes a mesa on an outermost periphery, the mesa including a side wall having a forward tapered shape in the nitride semiconductor device according to any one of the first to sixth aspects.

Consequently, the electric field concentration in the termination region can be further relaxed, so that the withstand voltage of the nitride semiconductor device can be further increased.

A nitride semiconductor device according to an eighth aspect of the present disclosure is configured such that the side wall of the mesa on the outermost periphery has a taper angle less than or equal to 35 degrees in the nitride semiconductor device according to the seventh aspect.

Consequently, the electric field concentration in the termination region can be further relaxed, so that the withstand voltage of the nitride semiconductor device can be further increased.

A nitride semiconductor device according to a ninth aspect of the present disclosure is configured such that the side wall of the mesa on the outermost periphery has a taper angle more than or equal to 10 degrees in the nitride semiconductor device according to the eighth aspect.

Consequently, the electric field concentration in the termination region can be further relaxed, so that the withstand voltage of the nitride semiconductor device can be further increased.

A nitride semiconductor device according to a tenth aspect of the present disclosure is configured such that the side wall of the mesa on the outermost periphery has a taper angle more than or equal to 50 degrees in the nitride semiconductor device according to the seventh or eighth aspect.

Consequently, the electric field concentration in the termination region can be further relaxed, so that the withstand voltage of the nitride semiconductor device can be further increased.

A nitride semiconductor device according to an eleventh aspect of the present disclosure is configured such that the side walls of the mesas at the first step and the second step in the mesa structure are continuously connected to each other in the nitride semiconductor device according to any one of the first to tenth aspects.

Consequently, the electric field concentration in the termination region can be further relaxed, so that the withstand voltage of the nitride semiconductor device can be further increased.

A nitride semiconductor device according to a twelfth aspect of the present disclosure is configured such that each of the side walls at the first step and the second step in the mesa structure has a taper angle continuously decreasing in the nitride semiconductor device according to any one of the first to eleventh aspects.

Consequently, the electric field concentration in the termination region can be further relaxed, so that the withstand voltage of the nitride semiconductor device can be further increased.

Hereinafter, exemplary embodiments will be specifically described with reference to the drawings.

Each of the exemplary embodiments described below shows a comprehensive or specific example. The exemplary embodiments below show numerical values, shapes, materials, components, placement positions and connection modes of the components, steps, order of the steps, and the like, which are merely examples and are not intended to limit the present disclosure. The components in the exemplary embodiments below include a component that is not described in an independent claim and that is described as an optional component.

Each of the drawings is a schematic diagram, and is not necessarily strictly illustrated. Thus, scales and the like do not necessarily coincide in the respective drawings, for example. Each of the drawings denotes substantially the same components with the same reference numerals, and duplicated description will not be described or will be simplified.

Then, terms indicating relationships between elements, such as parallel and perpendicular, terms indicating shapes of elements, such as rectangular and trapezoidal, and numerical ranges are herein not expressions representing only strict meanings, but are expressions representing meaning of including substantially equivalent ranges, such as differences of about several percent.

Additionally, a “thickness direction” of a substrate herein refers to a direction perpendicular to a main surface of the substrate. The thickness direction aligns with a stacked direction of semiconductor layers, and is also referred to as a “vertical direction”. Then, a direction parallel to the main surface of the substrate may be referred to as a “lateral direction”. A “vertical” semiconductor device means a device in which a main path of a current such as a drain current or a forward current is provided in the vertical direction, that is, a device in which a main current passes through the substrate in the vertical direction. A “lateral” semiconductor device means a device in which a main path of a current such as a drain current or a forward current is provided in the lateral direction, that is, a main current does not pass through the substrate.

Then, a first side on which the mesa structure according to the present disclosure is provided on the substrate is herein regarded as “above” or an “upper side”, and a second side opposite to the first side is herein regarded as “below” or a “lower side”. The terms “above” and “below” do not refer to an upward direction (vertically upward) and a downward direction (vertically downward) in absolute space recognition, but are used as terms defined by a relative positional relationship based on a stacked order in a stacked structure. Then, the terms “above” and “below” are applied not only when two components are spaced apart from each other and another component exists between the two components, but also when the two components are disposed in close contact with each other and the two components are in contact.

“Plan view” herein refers to view from a direction perpendicular to the main surface of the substrate of the nitride semiconductor device, that is, view from the front of the main surface of the substrate, unless otherwise specified.

Then, the n-type and the p-type indicate conductivity types of a semiconductor, and are conductivity types having opposite polarities to each other. An n⁺-type indicates a state in which an n-type dopant is added to a semiconductor at a high concentration, the state being so-called heavy doping. An n⁻-type indicates a state in which the n-type dopant is added to the semiconductor at a low concentration, the state being so-called light doping. The n⁺-type and the n⁻-type are each an example of the n-type, and may be described as the n-type without being distinguished from each other. The same applies to the p-type, a p⁺-type, and a p⁻-type.

A “main component” herein means a component having the highest content rate among all components constituting a member. For example, a component having a content rate more than or equal to 50% is a main component. The component is a material, an element, a compound, or the like. Then, “member A is composed of component B” means that member A substantially contains only component B. However, member A may contain not only component B, but also impurities that cannot be prevented from being mixed in manufacturing. Such unavoidable impurities have a content rate less than or equal to 1%, for example.

Then, AlGaN herein represents ternary mixed crystal AlₓGa₁₋ₓN (0<x<1). Hereinafter, a multicomponent mixed crystal is abbreviated as an arrangement of constituent element symbols, such as AlInN, GaInN, or the like. For example, AlₓGa_{1-x-y}In_{y}N (0<x<1, 0<y<1, and 0<x+y<1), which is an example of a nitride semiconductor, is abbreviated as AlGaInN. Composition ratios of Al, Ga, and In are represented by x, 1-x-y, and y, respectively.

Ordinal numbers such as “first” and “second” herein do not mean the number or order of components unless otherwise specified, and are used for the purpose of avoiding confusion of components identical in kind and distinguishing the components.

### First Exemplary Embodiment

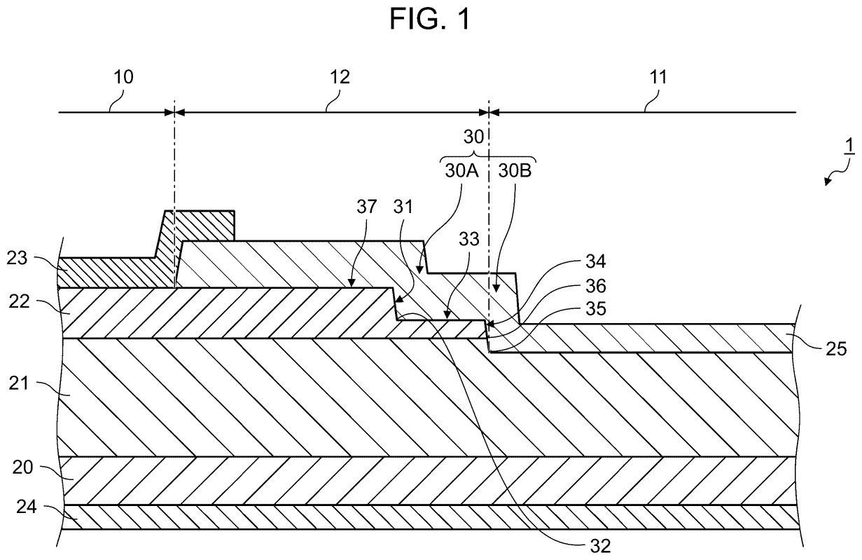

First, a nitride semiconductor device according to a first exemplary embodiment will be described with reference to FIG. 1. FIG. 1 is a sectional view of nitride semiconductor device 1 according to the present exemplary embodiment.

Nitride semiconductor device 1 illustrated in FIG. 1 includes active region 10, inactive region 11, and termination region 12.

Active region 10 is a main operation region of nitride semiconductor device 1, and is also referred to as a device region. Active region 10 includes a vertical field effect transistor (FET), for example. During operation of nitride semiconductor device 1, a drain current flows in active region 10.

Inactive region 11 surrounds a periphery of active region 10, and is also referred to as a peripheral region or an element isolation region.

Termination region 12 is provided between active region 10 and inactive region 11. Termination region 12 is provided with mesa structure 30 with two or more steps. Consequently, withstand voltage of nitride semiconductor device 1 can be increased. Details of mesa structure 30 will be described later.

As illustrated in FIG. 1, nitride semiconductor device 1 includes substrate 20, first nitride semiconductor layer 21, second nitride semiconductor layer 22, source electrode 23, drain electrode 24, and insulating film 25.

Substrate 20 is composed of a conductive nitride semiconductor as a main component. Specifically, substrate 20 is composed of GaN doped with an n-type dopant such as Si as a main component. Although substrate 20 has a rectangular shape in plan view, for example, it is not limited to the shape. Although substrate 20 has a thickness of 300 μm and is composed of GaN of the n⁺-type having a carrier concentration of 5×10¹⁸ cm⁻³, for example, it is not limited to this configuration. Substrate 20 may be a Si substrate, a SiC substrate, a ZnO substrate, a gallium oxide substrate, a diamond substrate, or the like. Substrate 20 may be also a conductive substrate such as a graphite substrate containing graphene.

First nitride semiconductor layer 21 has a conductivity of the n-type, and may be referred to as a drift layer. First nitride semiconductor layer 21 is provided above substrate 20. Although first nitride semiconductor layer 21 is specifically provided in contact with an upper surface of substrate 20, the present invention is not limited thereto. One or more other layers such as a buffer layer may be provided between first nitride semiconductor layer 21 and substrate 20.

First nitride semiconductor layer 21 is composed of GaN doped with an n-type dopant as a main component. For example, first nitride semiconductor layer 21 is a film composed of GaN of the n⁻-type having a film thickness of 8 μm. The n-type dopant of first nitride semiconductor layer 21 has a concentration from 1×10¹⁵ cm⁻³ to 1×10¹⁷ cm⁻³ inclusive, for example, and has a concentration of 1×10¹⁶ cm⁻³, for example. First nitride semiconductor layer 21 has a carbon concentration (C concentration) from 1×10¹⁵ cm⁻³ to 2×10¹⁷ cm⁻³ inclusive, for example.

The film thickness of first nitride semiconductor layer 21 and the concentration of the n-type dopant are not particularly limited. Although the n-type dopant in first nitride semiconductor layer 21 has a concentration uniform in a layer, the n-type dopant is not limited to the concentration. For example, the n-type dopant in first nitride semiconductor layer 21 may have a concentration decreasing or increasing in a depth direction. Alternatively, first nitride semiconductor layer 21 may have a stacked structure of a plurality of nitride semiconductor layers each having a different concentration of the n-type dopant.

Second nitride semiconductor layer 22 has a conductivity of the p-type, and may be referred to as a block layer or a current block layer. Second nitride semiconductor layer 22 is provided to block a leak current between a source and a drain. Second nitride semiconductor layer 22 is provided above first nitride semiconductor layer 21. Although second nitride semiconductor layer 22 is specifically provided in contact with an upper surface of first nitride semiconductor layer 21, the present invention is not limited thereto. Between second nitride semiconductor layer 22 and first nitride semiconductor layer 21, one or more other layers such as an undoped nitride semiconductor layer and a nitride semiconductor layer to which carbon is added to increase resistance may be provided. For example, a GaN layer of an i-type or a GaN layer doped with C may be provided on the upper surface of first nitride semiconductor layer 21.

Second nitride semiconductor layer 22 is composed of GaN doped with a p-type dopant as a main component. For example, second nitride semiconductor layer 22 is a film composed of GaN of the p-type having a thickness of 300 nm. The p-type dopant of second nitride semiconductor layer 22 has a concentration less than or equal to 5×10¹⁹ cm⁻³, for example. Alternatively, the p-type dopant of second nitride semiconductor layer 22 has a concentration more than or equal to 2×10¹⁶ cm⁻³, for example. Although the p-type dopant of second nitride semiconductor layer 22 may have a concentration of 1×10¹⁷ cm⁻³, for example, the concentration is not limited thereto. Although second nitride semiconductor layer 22 has a film thickness from 100 nm to 500 nm inclusive, for example, the film thickness is not limited thereto.

The p-type dopant in second nitride semiconductor layer 22 has a concentration uniform in a layer in the present exemplary embodiment. The term “uniform” means not only completely uniform but also substantially uniform. A range of the substantially uniform concentration can be regarded as a range with a maximum value that is twice or less an average value and a minimum value that is ½ or more of the average value when concentration distribution is acquired in the depth direction, for example. The p-type dopant in second nitride semiconductor layer 22 does not necessarily have a uniform concentration. For example, the p-type dopant may have a concentration that continuously changes in a predetermined direction such as a thickness direction, a stacked structure having a plurality of concentrations, or a concentration that is locally different. When the p-type dopant has a non-uniform concentration, an exemplary value of the concentration of the p-type dopant in second nitride semiconductor layer 22 is represented by an average value of concentrations of the p-type dopant in second nitride semiconductor layer 22.

Source electrode 23 is an example of a first electrode in direct contact with second nitride semiconductor layer 22. Specifically, source electrode 23 is in contact with the upper surface of second nitride semiconductor layer 22 in active region 10. In the present exemplary embodiment, source electrode 23 is provided covering a part of an upper surface of insulating film 25 in termination region 12. Source electrode 23 is electrically connected to a channel layer not illustrated in FIG. 1 in active region 10. Source electrode 23 contains a conductive material such as metal of Ti, Al, Hf, Ni, Pt, Au, Mo, Pd, or the like as a main component. Source electrode 23 has a single-layer or stacked structure of a conductive film.

Drain electrode 24 is an example of a second electrode provided below substrate 20. Specifically, drain electrode 24 is provided in contact with a lower surface of substrate 20. Drain electrode 24 is provided entirely or partially on the lower surface of substrate 20, for example. Drain electrode 24 contains a conductive material such as metal such as Ti, Al, Hf, Ni, Pt, Au, Mo, or Pd as a main component, the conductive material being in ohmic contact with substrate 20. Drain electrode 24 has a single-layer or stacked structure of a conductive film.

Insulating film 25 is provided in termination region 12 and inactive region 11. In the present exemplary embodiment, an end closest to inactive region 11 in plan view in a contact surface between source electrode 23 and second nitride semiconductor layer 22 is regarded as a boundary between active region 10 and termination region 12. In plan view, a boundary between termination region 12 and inactive region 11 is regarded as lower end 35 of side wall 34 of the mesa at the second step of mesa structure 30.

Insulating film 25 may not be provided. Insulating film 25 may have a single-layer or stacked structure of an insulating film containing SiO₂, SiN, SiON, Al₂O₃, or the like as a main component.

Although not illustrated in FIG. 1, a channel layer and a gate electrode are provided in active region 10. The channel layer is a nitride semiconductor layer including a channel. The channel is a path capable of electrically connecting source electrode 23 and drain electrode 24, and conduction (on) and non-conduction (off) of the electrodes are switched in accordance with a potential applied to the gate electrode.

For example, the channel layer has a stacked structure including a third nitride semiconductor layer and a fourth nitride semiconductor layer having a larger band gap than the third nitride semiconductor layer. For example, the third nitride semiconductor layer contains undoped GaN as a main component, and the fourth nitride semiconductor layer contains undoped AlGaN as a main component. A two-dimensional electron gas (2DEG) is generated near a hetero interface between GaN and AlGaN by piezoelectric polarization caused by a lattice constant difference between GaN and AlGaN, and spontaneous polarization caused by atomic arrangement of GaN. The 2DEG is used as a channel of nitride semiconductor device 1. That is, conduction and non-conduction between the source and the drain can be switched by partially controlling the generation of 2DEG using a potential applied to the gate electrode.

Active region 10 is provided with an opening for bringing the channel layer into contact with first nitride semiconductor layer 21. The opening may be referred to as a gate opening, a vertical conduction opening, or a conduction opening. For example, the conduction opening is formed passing through second nitride semiconductor layer 22 to reach first nitride semiconductor layer 21. The channel layer is provided along an inner surface of the conduction opening while being in contact with not only first nitride semiconductor layer 21 on a bottom surface of the conduction opening, but also source electrode 23 outside the conduction opening. This configuration enables reducing on-resistance.

The gate electrode is provided above the channel layer. The gate electrode contains a conductive material such as metal of Pd, Ni, or the like as a main component. Although the gate electrode may be provided in contact with an upper surface of the channel layer, the gate electrode is not limited to this placement. For example, a nitride semiconductor layer of the p-type may be provided between the gate electrode and the channel layer. The nitride semiconductor layer of the p-type is also referred to as a p-type gate layer, and contains GaN of the p-type or AlGaN of the p-type as a main component, for example. When a nitride semiconductor layer of the p-type is provided, the 2DEG in the direction immediately below the nitride semiconductor layer of the p-type can be eliminated, thus achieving normally-off of the FET. The gate electrode and/or the p-type gate layer may be provided at a position overlapping the bottom surface of the conduction opening in plan view, or may be provided outside the conduction opening. The gate electrode and/or the p-type gate layer are electrically separated from source electrode 23.

Instead of the p-type gate layer, an insulating oxide film, a nitride film, an oxynitride film, or the like may be provided. The 2DEG may not be used as the channel, and the channel layer may be a nitride semiconductor layer of the n-type or a nitride semiconductor layer of the p-type. The channel layer may be provided inside with an inversion channel formed using a potential applied to the gate electrode.

A method for manufacturing nitride semiconductor device 1 according to the present exemplary embodiment is as follows, for example.

First, a semiconductor film to be a base of first nitride semiconductor layer 21 and second nitride semiconductor layer 22 is formed on substrate 20 by crystal growth promoted by an epitaxial growth method such as a metal organic chemical vapor deposition (MOCVD) method or a hydride vapor phase epitaxy (HVPE) method. Adjusting growth conditions such as a raw material, growth temperature, and growth time, enables a composition, a film thickness, an impurity concentration, and the like to be set to values suitable for each layer.

Next, an FET structure is formed in active region 10. For example, after the conduction opening is formed by dry etching or the like, a channel layer is formed by crystal regrowth of a nitride semiconductor. At this time, a p-type gate layer may be formed continuously from the channel layer.

Next, mesa structure 30 is formed in termination region 12. Mesa structure 30 can be formed by performing etching multiple times in accordance with the number of steps of mesas. After mesa structure 30 is formed, insulating film 25 is formed by a plasma chemical vapor deposition (CVD) method, a thermal CVD method, a sputtering method, a coating method, or the like. After insulating film 25 is formed, a part of insulating film 25 is removed by etching. After that, source electrode 23, a gate electrode, and the like are formed. Source electrode 23 and the gate electrode are each formed by forming a conductive film by electron beam (EB) vapor deposition, sputtering, or the like, and then patterning the conductive film into a predetermined shape by lift-off, etching, or the like. Mesa structure 30 may be formed after source electrode 23 and the gate electrode are formed. Then, drain electrode 24 is formed on a lower surface of substrate 20 by the EB vapor deposition, sputtering, or the like.

As described above, nitride semiconductor device 1 illustrated in FIG. 1 can be manufactured. The method for manufacturing nitride semiconductor device 1 described above is merely an example, and can be appropriately changed.

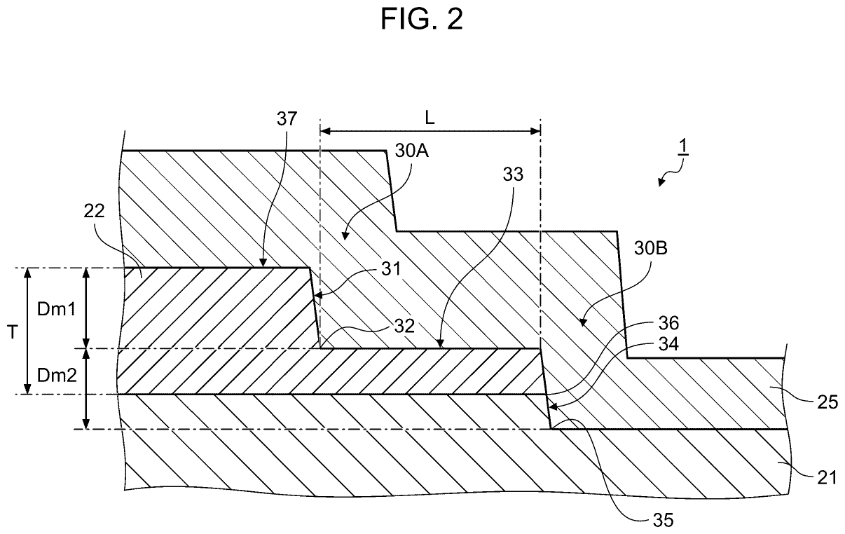

Subsequently, mesa structure 30 will be described in detail with reference to FIG. 2. FIG. 2 is an enlarged sectional view of a main part of nitride semiconductor device 1 according to the present exemplary embodiment. Specifically, FIG. 2 illustrates mesa structure 30 provided in termination region 12 and a peripheral structure thereof.

Mesa structure 30 includes two or more steps of mesas. The mesa means a step formed by partially removing one or more semiconductor layers. The mesa is a part of a surface of a semiconductor layer and has at least a side wall inclined or perpendicular to a main surface of the semiconductor layer. In the present exemplary embodiment, the mesa further includes an upper surface connected to an upper end of the side wall and a bottom surface connected to a lower end of the side wall. For example, the upper surface and the bottom surface of the mesa are each a plane parallel to the main surface of the substrate. The upper surface of the mesa is located on a bottom surface of a mesa located one step up. In other words, the bottom surface of the mesa is located on an upper surface of a mesa located one step down. The order of a mesa is represented by a numerical value counted from above. That is, a mesa having a larger ordinal number is closer to substrate 20 than a mesa having a smaller ordinal number.

FIGS. 1 and 2 show an example in which mesa structure 30 includes two steps of mesas 30A and 30B. Mesa 30A is located at a first step, and mesa 30B is located at a second step. Mesa 30A includes side wall 31 and bottom surface 33. Lower end 32 of side wall 31 is located at a position in second nitride semiconductor layer 22. Bottom surface 33 extends from lower end 32 of side wall 31 toward inactive region 11. Side wall 31 and bottom surface 33 are each a part of a surface of second nitride semiconductor layer 22. Bottom surface 33 is located on an upper surface of mesa 30B. Mesa 30B includes side wall 34. Lower end 35 of side wall 34 reaches first nitride semiconductor layer 21. That is, interface end 36 appears on side wall 34, interface end 36 being an end of an interface between first nitride semiconductor layer 21 and second nitride semiconductor layer 22.

Although upper surface 37 of mesa 30A at the first step is a part of an uppermost surface of second nitride semiconductor layer 22, for example, upper surface 37 is not limited thereto. The example illustrated in FIG. 1 shows source electrode 23 provided in contact with the uppermost surface of second nitride semiconductor layer 22. Thus, a lower surface of source electrode 23 and upper surface 37 of mesa 30A at the first step are located at the same height. The “height” herein is a distance from a main surface of substrate 20 unless otherwise specified.

As illustrated in FIG. 2, mesa depth Dm1 of mesa 30A at the first step is half or more of film thickness T of second nitride semiconductor layer 22. The mesa depth is represented by a distance between the upper surface and the lower surface of the mesa in the thickness direction of the semiconductor layer. Mesa depth Dm1 is half or more of film thickness T, so that remnant film thickness (T−Dm1) of second nitride semiconductor layer 22 is reduced, the remnant being acquired after mesa 30A at the first step is formed. The remnant of second nitride semiconductor layer 22 is a part of second nitride semiconductor layer 22, the part having an upper surface located on bottom surface 33 of mesa 30A.

Electric field concentration is relaxed in termination region 12 because mesa structure 30 having two or more steps is provided. Specifically, an electric field is dispersed into lower end 32 of side wall 31 of mesa 30A at the first step and lower end 35 of side wall 34 of mesa 30B at the second step. At this time, a larger electric field is likely to be applied to lower end 32 of mesa 30A at the first step than lower end 35 of mesa 30B at the second step for shallow mesa depth Dm1, and a larger electric field is likely to be applied to lower end 35 of mesa 30B at the second step than lower end 32 of mesa 30A at the first step for deep mesa depth Dm1. As described above, positions where electric fields are likely to be concentrated are switched depending on a value of mesa depth Dm1. Thus, when mesa depth Dm1 is set to a depth half or more of film thickness T, a difference between an electric field applied to lower end 32 of mesa 30A at the first step and an electric field applied to lower end 35 of mesa 30B at the second step can be reduced. Consequently, the electric field in termination region 12 can be effectively dispersed into lower ends 32 and 35, so that the withstand voltage of nitride semiconductor device 1 can be increased.

Although mesa depth Dm2 of mesa 30B at the second step is equal to mesa depth Dm1 of mesa 30A at the first step in the present exemplary embodiment, the depths are not limited thereto. Mesa depth Dm2 of mesa 30B at the second step may be more than mesa depth Dm1 of mesa 30A at the first step.

In the present exemplary embodiment, bottom surface 33 of mesa 30A at the first step has length L less than or equal to 10 μm. Consequently, termination region 12 can be reduced in area, so that downsizing of nitride semiconductor device 1 or increase in area of active region 10 can be achieved.

As length L of bottom surface 33 is shortened, termination region 12 can be more reduced in area. Thus, length L may be less than or equal to 5 μm, less than or equal to 3 μm, or less than or equal to 2 μm, for example. Bottom surface 33 may have length L more than or equal to 1 μm, for example.

### Second Exemplary Embodiment

Subsequently, a second exemplary embodiment will be described.

The second exemplary embodiment is mainly different from the first exemplary embodiment in that a mesa at the first step has a deeper depth. Hereinafter, differences from the first exemplary embodiment will be mainly described, and description of common points will not be described or will be simplified.

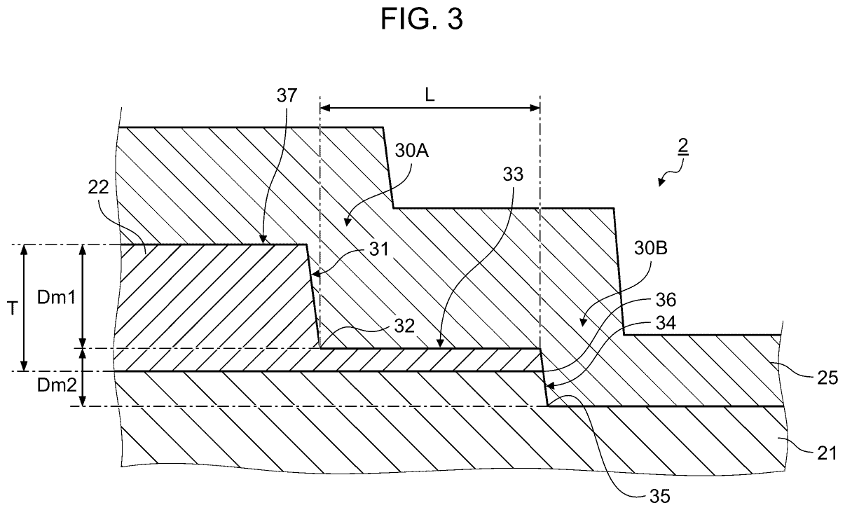

FIG. 3 is an enlarged sectional view of a main part of nitride semiconductor device 2 according to the present exemplary embodiment. As illustrated in FIG. 3, mesa depth Dm1 of mesa 30A at the first step is ⅔ or more of film thickness T of second nitride semiconductor layer 22 in the present exemplary embodiment. That is, remnant film thickness (T−Dm1) of second nitride semiconductor layer 22 is less than or equal to ⅓ of film thickness T in the present exemplary embodiment. Remnant film thickness (T−Dm1) is at least 1 nm, but may have a film thickness more than or equal to 5 nm, or more than or equal to 10 nm.

Although details will be described later together with results of an electric field simulation, an optimum ratio of mesa depth ratio Dm1/Dm2 may exist. Remnant film thickness (T−Dm1) can be determined based on mesa depth ratio Dm1/Dm2. For example, remnant film thickness (T−Dm1) may be less than or equal to ¼, less than or equal to ⅕, or less than or equal to 1/10 of film thickness T. Meanwhile, when remnant film thickness (T−Dm1) is increased to some extent, such as more than or equal to 5 nm, adjustment of the film thickness of the remnant is facilitated. That is, an allowable range of a manufacturing error and the like during manufacturing of mesa 30A is widened, so that a yield can be increased.

Although mesa depth Dm2 of mesa 30B at the second step is shallower than mesa depth Dm1 of mesa 30A at the first step in the present exemplary embodiment, the depths are not limited thereto. Mesa depth Dm2 of mesa 30B at the second step may be equal to mesa depth Dm1 of mesa 30A at the first step.

### Third Exemplary Embodiment

Subsequently, a third exemplary embodiment will be described.

The third exemplary embodiment is different from the first exemplary embodiment mainly in a magnitude relationship between a mesa depth at the first step and a mesa depth at the second step. Hereinafter, differences from the first exemplary embodiment will be mainly described, and description of common points will not be described or will be simplified.

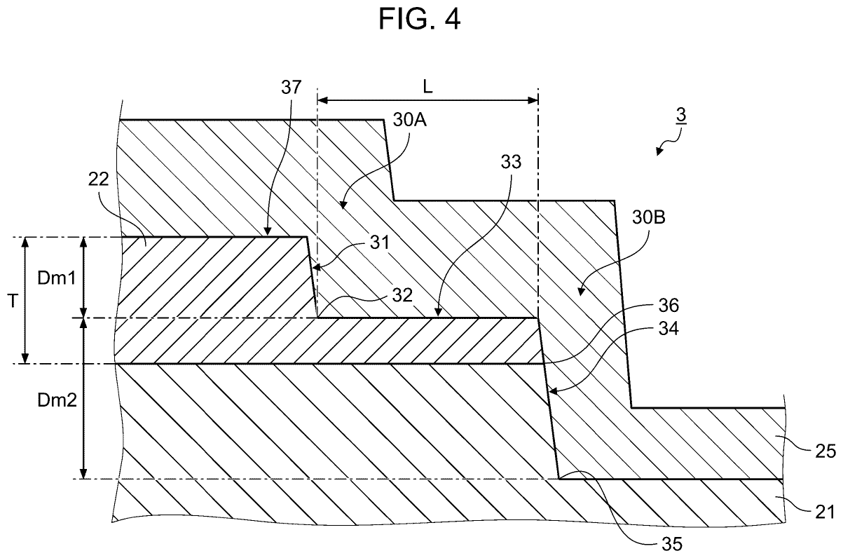

FIG. 4 is an enlarged sectional view of a main part of nitride semiconductor device 3 according to the present exemplary embodiment. As illustrated in FIG. 4, mesa depth Dm1 of mesa 30A at the first step is shallower than mesa depth Dm2 of mesa 30B at the second step in the present exemplary embodiment. Consequently, an electric field is likely to be evenly dispersed into lower end 32 of mesa 30A at the first step and lower end 35 of mesa 30B at the second step. Thus, withstand voltage of nitride semiconductor device 3 can be further increased.

Although details will be described later together with results of an electric field simulation, mesa depth Dm1 may be half or less of mesa depth Dm2. Alternatively, mesa depth Dm1 may be less than or equal to ⅓ of mesa depth Dm2, or less than or equal to ¼ thereof. In a range where mesa depth Dm1 is half or more of film thickness T, an optimum mesa depth ratio Dm1/Dm2 may exist.

### Fourth Exemplary Embodiment

Subsequently, a fourth exemplary embodiment will be described.

The fourth exemplary embodiment is different from the first exemplary embodiment mainly in that a taper angle of a mesa at the first step is different from a taper angle of a mesa at the second step. Hereinafter, differences from the first exemplary embodiment will be mainly described, and description of common points will not be described or will be simplified.

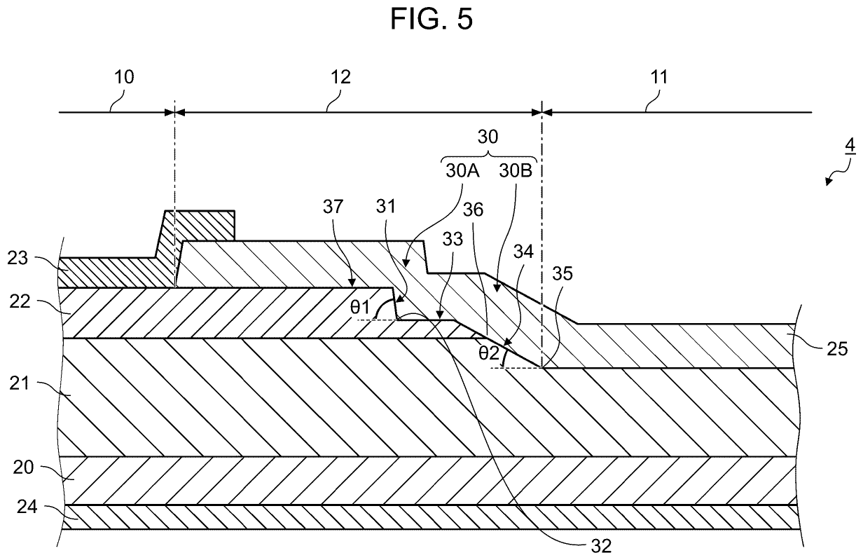

FIG. 5 is a sectional view of nitride semiconductor device 4 according to the present exemplary embodiment. As illustrated in FIG. 5, side wall 31 of mesa 30A at the first step and side wall 34 of mesa 30B at the second step each have a forward tapered shape in the present exemplary embodiment. That is, both taper angle θ1 of side wall 31 and taper angle θ2 of side wall 34 are each larger than 0 degrees and smaller than 90 degrees. Taper angle θ1 is defined by a plane parallel to a main surface of substrate 20 and side wall 31 in second nitride semiconductor layer 22. Taper angle θ1 has a value obtained by subtracting an angle defined by side wall 31 and bottom surface 33 from 180 degrees. Taper angle θ2 is defined by a plane parallel to the main surface of substrate 20 and side wall 34 in first nitride semiconductor layer 21. Taper angle θ2 has a value obtained by subtracting an angle defined by side wall 34 and a bottom surface of mesa 30B from 180 degrees. Side wall 31 and side wall 34 are each not necessarily a straight line (not illustrated). This configuration causes each of side wall 31 of mesa 30A at the first step and side wall 34 of mesa 30B at the second step to have a taper angle that is not constant. Taper angle θ1 of side wall 31 when the taper angle continuously changes is regarded as a taper angle at the midpoint of side wall 31 in sectional view. Taper angle θ2 of side wall 34 is regarded as a taper angle at the midpoint of side wall 34 in sectional view.

Alternatively, taper angle θ1 may be 90 degrees. That is, side wall 31 and bottom surface 33 may be perpendicular to each other. In the present exemplary embodiment, the mesa on the outermost periphery in mesa structure 30, that is, mesa 30B may have side wall 34 in a forward tapered shape. That is, taper angle θ2 of side wall 34 may be less than 90 degrees. Taper angle θ2 is smaller than taper angle θ1. Side wall 34 of mesa 30B on the outermost periphery has the forward tapered shape, so that electric field concentration in termination region 12 can be further relaxed. Thus, withstand voltage of nitride semiconductor device 4 can be further increased.

Although details will be described later together with results of an electric field simulation, electric field intensity tends to increase around 45 degrees within a range where taper angle θ2 is less than 90 degrees. Thus, taper angle θ2 may be less than or equal to 35 degrees, for example. Alternatively, taper angle θ2 may be more than or equal to 10 degrees. When side wall 34 is gently inclined, the electric field concentration can be further relaxed. Alternatively, taper angle θ2 may be more than or equal to 50 degrees. When side wall 34 is steeply inclined, the electric field concentration can be further relaxed. When side wall 34 is steeply inclined, termination region 12 can be reduced in area. Thus, downsizing of nitride semiconductor device 4 or increase in area of active region 10 can be achieved.

Sizes of taper angles θ1 and θ2 can be adjusted by changing a shape of an end of an opening of a resist pattern formed when mesas 30A and 30B are formed by etching. Specifically, an inclination is formed at the end of the opening of the resist pattern. When second nitride semiconductor layer 22 and first nitride semiconductor layer 21 are removed by etching, the inclination of the end of the opening of the resist pattern is transferred to the semiconductor layers to form inclined side walls 31 and 34. The inclination of the end of the opening of the resist pattern can be adjusted by changing baking temperature of the resist pattern, for example. For example, the inclination becomes gentle by baking at a high temperature, and the inclination can be made steep or perpendicular by baking at a low temperature.

As with nitride semiconductor devices 1 to 3 according to the first to third exemplary embodiments, nitride semiconductor device 4 according to the present exemplary embodiment has mesa depth Dm1 that may be half or more, or ⅔ or more of film thickness T of second nitride semiconductor layer 22. Additionally, mesa depth Dm1 of mesa 30A at the first step may be less than mesa depth Dm2 of mesa 30B at the second step.

### Fifth Exemplary Embodiment

Subsequently, a fifth exemplary embodiment will be described.

The fifth exemplary embodiment is mainly different from the first exemplary embodiment in that a bottom surface of a mesa at the first step, that is, an upper surface of a mesa at the second step, is not provided. Hereinafter, differences from the first exemplary embodiment will be mainly described, and description of common points will not be described or will be simplified.

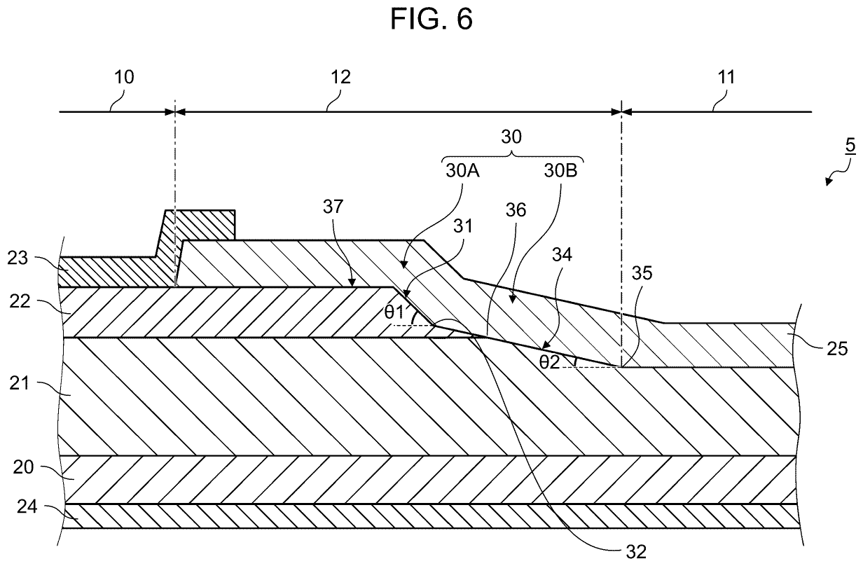

FIG. 6 is a sectional view of nitride semiconductor device 5 according to the present exemplary embodiment. As illustrated in FIG. 6, bottom surface 33 of mesa 30A is not provided. Lower end 32 of side wall 31 of mesa 30A at the first step continues to an upper end of side wall 34 of mesa 30B at the second step. Lower end 32 of side wall 31 is a connection point between side wall 31 and side wall 34, and can be regarded as a change point of inclination.

As in the fourth exemplary embodiment, taper angle θ1 of side wall 31 is larger than taper angle θ2 of side wall 34 in the present exemplary embodiment. Taper angles θ1 and θ2 are each more than or equal to 0 degrees and less than 90 degrees. Taper angle θ2 is from 10 degrees to 35 degrees inclusive, for example, but may be more than or equal to 50 degrees and less than 90 degrees.

As described above, even when bottom surface 33 of mesa 30A is not provided, electric field concentration in mesa structure 30 can be relaxed as in other exemplary embodiments. Thus, withstand voltage of nitride semiconductor device 5 can be increased. Then, bottom surface 33 is not provided, thus length L of bottom surface 33 can be regarded as 0 μm. Thus, termination region 12 can be reduced in area, so that downsizing of nitride semiconductor device 5 or increase in area of active region 10 can be achieved.

As with nitride semiconductor devices 1 to 3 according to the first to third exemplary embodiments, nitride semiconductor device 5 according to the present exemplary embodiment has mesa depth Dm1 that may be half or more, or ⅔ or more of film thickness T of second nitride semiconductor layer 22. Additionally, mesa depth Dm1 of mesa 30A at the first step may be less than mesa depth Dm2 of mesa 30B at the second step.

### Sixth Exemplary Embodiment

Subsequently, a sixth exemplary embodiment will be described.

The sixth exemplary embodiment is mainly different from the fifth exemplary embodiment in that a taper angle of each of a side wall of a mesa at the first step and a side wall of a mesa at the second step continuously decreases. Hereinafter, differences from the fifth exemplary embodiment will be mainly described, and description of common points will not be described or will be simplified.

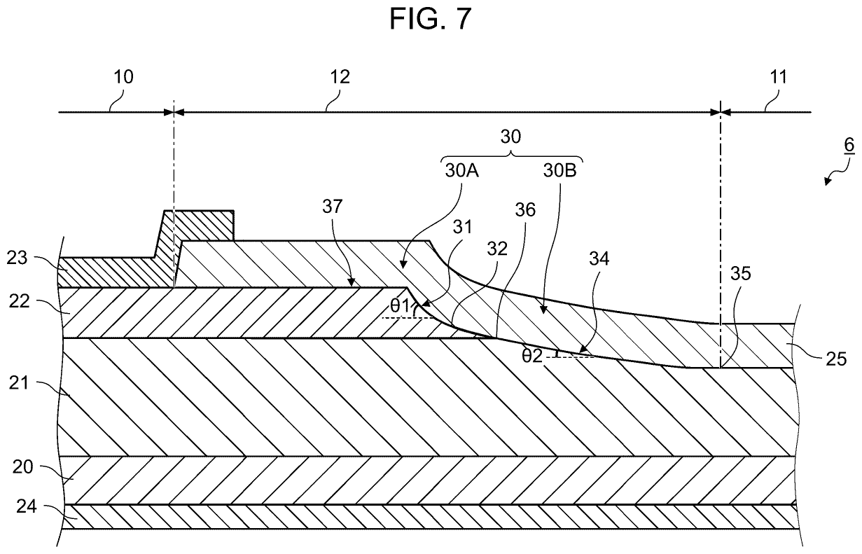

FIG. 7 is a sectional view of nitride semiconductor device 6 according to the present exemplary embodiment. As illustrated in FIG. 7, each of side wall 31 of mesa 30A at the first step and side wall 34 of mesa 30B at the second step has a taper angle that is not constant. Specifically, the taper angle of each of side walls 31 and 34 continuously decreases. As described above, when the taper angle continuously changes, a position where the taper angle becomes 45 degrees is regarded as lower end 32 of side wall 31, for example. Taper angle θ1 of side wall 31 is regarded as a taper angle at the midpoint of side wall 31 in sectional view. Taper angle θ2 of side wall 34 is regarded as a taper angle at the midpoint of side wall 34 in sectional view. In the present exemplary embodiment, a rate of change in the taper angle of side wall 31 is larger than a rate of change in the taper angle of side wall 34, for example. That is, while inclination of side wall 31 changes steeply, inclination of side wall 34 changes gently.

As described above, even when bottom surface 33 of mesa 30A is not provided and the taper angle continuously changes, electric field concentration in mesa structure 30 can be relaxed as in other exemplary embodiments. Thus, withstand voltage of nitride semiconductor device 6 can be increased. Then, bottom surface 33 is not provided, thus length L of bottom surface 33 can be regarded as 0 μm. Thus, termination region 12 can be reduced in area, so that downsizing of nitride semiconductor device 6 or increase in area of active region 10 can be achieved.

As with nitride semiconductor devices 1 to 3 according to the first to third exemplary embodiments, nitride semiconductor device 6 according to the present exemplary embodiment has mesa depth Dm1 that may be half or more, or ⅔ or more of film thickness T of second nitride semiconductor layer 22. Additionally, mesa depth Dm1 of mesa 30A at the first step may be less than mesa depth Dm2 of mesa 30B at the second step.

### Simulation Results

Subsequently, results of a plurality of electric field simulations performed by the present inventors will be described.

The plurality of electric field simulations was performed to calculate distribution of electric field intensities generated in mesa structure 30 and its periphery under a plurality of conditions. Change in the electric field intensity at lower end 32 of side wall 31 of mesa 30A and lower end 35 of side wall 34 of mesa 30B under different conditions was studied.

Main conditions common to the plurality of electric field simulations are as follows. A nitride semiconductor device to be simulated has a structure equivalent to that of nitride semiconductor device 1 illustrated in FIG. 1. Specifically, substrate 20 is a GaN substrate of the n⁻-type. First nitride semiconductor layer 21 is a GaN layer of the n⁻type having a thickness of 10 μm. Second nitride semiconductor layer 22 is a GaN layer of the p-type having a thickness of 300 nm. Upper surface 37 has a length of 40 μm from an end of source electrode 23 to an upper end of side wall 31.

First, results of relationships between a ratio of mesa depths Dm1 and Dm2 and the electric field intensity, the relationships being studied by the electric field simulations, will be described. The electric field simulations were performed in which conditions below were set as fixed values in addition to the common conditions described above. Taper angle θ1 of side wall 31 of mesa 30A and taper angle θ2 of side wall 34 of mesa 30B were each set to 20 degrees. Voltage Vd to be applied between drain electrode 24 and source electrode 23 was set to 1200 V. As parameters to be varied, length L of bottom surface 33 of mesa 30A and mesa depth ratio Dm1/Dm2 were set. Length L of bottom surface 33 was set to any one of 2 μm and 5 μm. Mesa depth ratio Dm 1/Dm2 was set in a range from 0.1 μm/0.9 μm to 1.0 μm/0.0 μm.

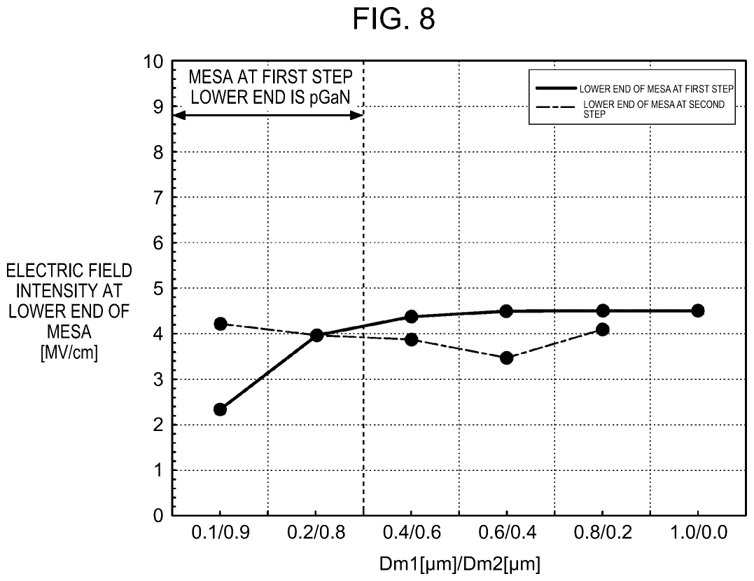

FIG. 8 is a diagram illustrating a relationship between a depth ratio between mesa 30A at the first step and mesa 30B at the second step, and electric field intensity. FIG. 8 shows a horizontal axis representing “mesa depth Dm1 of mesa 30A” “mesa depth Dm2 of mesa 30B” as a ratio of mesa depths. Mesa depths Dm1 and Dm2 are each indicated in units of μm. FIG. 8 shows a vertical axis representing electric field intensity applied to each of lower end 32 of mesa 30A at the first step and lower end 35 of mesa 30B at the second step. The electric field intensity is indicated in units of MV/cm. FIG. 8 illustrates the relationship when bottom surface 33 of mesa 30A has length L of 5 μm.

Second nitride semiconductor layer 22 is a GaN layer of the p-type having a thickness of 300 nm as described above as the common conditions, so that lower end 32 of mesa 30A is located in first nitride semiconductor layer 21 when mesa depth Dm1 of mesa 30A at the first step is in a range from 0.0 μm to 0.3 μm inclusive. As illustrated in FIG. 8, as mesa depth ratio Dm1/Dm2 increases, electric field intensity concentrated on lower end 32 of mesa 30A at the first step tends to decrease. Additionally, as mesa depth ratio Dm1/Dm2 increases, a magnitude relationship between the electric field intensity concentrated on lower end 32 of mesa 30A and electric field intensity concentrated on lower end 35 of mesa 30B is reversed. This reverse phenomenon is called electric field replacement. An electric field relaxation effect is high in a range before and after the electric field replacement occurs. Specifically, FIG. 8 reveals that electric field intensity with a higher value between electric field intensities applied to lower ends 32 and 35 decreases when ratio Dm1/Dm2 is in a range from 0.15/0.85 to 0.3/0.7 inclusive, and thus local electric field concentration is suppressed.

Even when bottom surface 33 had length L of 2 μm, results equivalent to the simulation results illustrated in FIG. 8 were obtained. Ratio Dm1/Dm2 of mesa depths has a value when electric field intensities concentrated on lower ends 32 and 35 are equal to each other, the value changing in accordance with length L of bottom surface 33 of mesa 30A. Specifically, mesa depth Dm1 of mesa 30A tends to decrease as length L increases. As illustrated in FIG. 8, when length L is 5 μm, for example, the electric field intensities concentrated on lower ends 32 and 35 are equal to each other to increase relaxation effect of the electric field concentration at ratio Dm 1/Dm2 that is 0.2 μm/0.8 μm. When length L is 2 μm, the electric field intensities concentrated on lower ends 32 and 35 are equal to each other to increase relaxation effect of the electric field concentration at ratio Dm1/Dm2 that is 0.3 μm/0.7 μm.

Next, results of relationships between taper angle θ2 of side wall 34 of mesa 30B at the second step and electric field intensity, the relationships being studied by the electric field simulations, will be described. The electric field simulations were performed in which conditions below were set as fixed values in addition to the common conditions described above. Taper angle θ1 of side wall 31 of mesa 30A was set to 70 degrees. Mesa depth ratio Dm1/Dm2 was set to 0.2 μm/1.0 μm. Length L of bottom surface 33 of mesa 30A was set to 5 μm. As parameters to be varied, voltage Vd applied between drain electrode 24 and source electrode 23, and taper angle θ2 of side wall 34 of mesa 30B were set. Specifically, voltage Vd was set to any one of 600 V and 1200 V. Taper angle θ2 was set in a range from 10 degrees to 70 degrees inclusive.

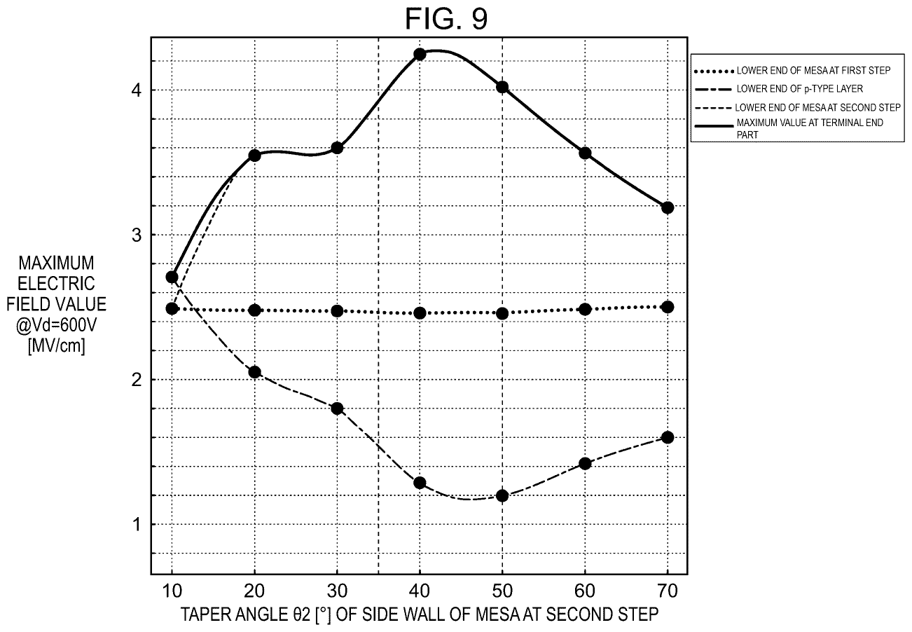

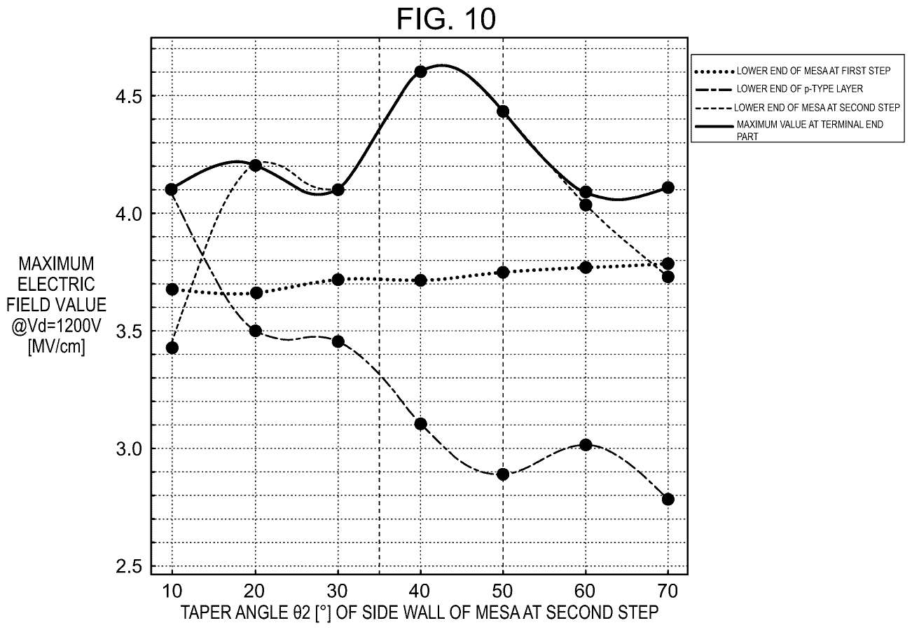

FIGS. 9 and 10 are each a diagram illustrating a relationship between taper angle θ2 of side wall 34 of mesa 30B at the second step and electric field intensity. FIG. 9 illustrates the relationship when voltage Vd is 600 V, and FIG. 10 illustrates the relationship when voltage Vd is 1200 V. FIGS. 9 and 10 each show a horizontal axis representing taper angle θ2. FIGS. 9 and 10 each show a vertical axis representing electric field intensity applied to each of lower end 32 of mesa 30A at the first step, lower end 35 of mesa 30B at the second step, and a lower end of a GaN layer of the p-type, that is, interface end 36, and a maximum value of electric field intensity at a terminal end part.

As illustrated in FIG. 9, maximum electric field intensity increases near taper angle θ2 of 45 degrees. Specifically, the maximum value of the electric field intensity exceeds about 4 MV/cm in a range where taper angle θ2 is larger than 35 degrees and less than 50 degrees. When taper angle θ2 is in a range less than or equal to 35 degrees, preferably in a range from 10 degrees to 35 degrees inclusive, the maximum value of the electric field intensity is suppressed at a low level. When taper angle θ2 is in a range more than or equal to 50 degrees, preferably in a range from 50 degrees to 70 degrees inclusive, the maximum value of the electric field intensity is suppressed at a low level. That is, FIG. 9 reveals that electric field concentration is relaxed by mesa structure 30 and withstand voltage of the nitride semiconductor device can be increased. FIG. 10 shows an example in which a similar tendency is found.

### Other Exemplary Embodiments

Although the nitride semiconductor device according to one or more aspects has been described above based on the exemplary embodiments, the present disclosure is not limited to these exemplary embodiments. Configurations in which various modifications conceivable by those skilled in the art are applied to the present exemplary embodiment and configurations constructed by combining components in different exemplary embodiments are also included in the scope of the present disclosure without departing from the gist of the present disclosure.

For example, mesa structure 30 may include mesas at three or more steps in each exemplary embodiment. This configuration causes a lower end of a mesa at the first step to be located in second nitride semiconductor layer 22, and causes a lower end of each of mesas at the second step and the third step to reach first nitride semiconductor layer 21. That is, an interface between first nitride semiconductor layer 21 and second nitride semiconductor layer 22 appears on a side wall of the mesa at the second step. A bottom surface of the mesa at the second step and a side wall and a bottom surface of the mesa at the third step are each a part of a surface of first nitride semiconductor layer 21. Similarly, when mesa structure 30 includes mesas at four or more steps, an interface between first nitride semiconductor layer 21 and second nitride semiconductor layer 22 appears on a side wall of the mesa at the second step, and bottom surfaces of the mesas at the second and subsequent steps and side walls of the mesas at the third and subsequent steps are each a part of the surface of first nitride semiconductor layer 21. Mesa structure 30 may include at least one mesa in which a taper angle of a side wall is not constant and varies.

When mesa structure 30 includes mesas at “n” or more steps, the mesas may include a mesa without including a bottom surface. That is, a side wall of a mesa at the “m−1”-th step may continue to a side wall of a mesa at the “m” th step as with nitride semiconductor devices 5 and 6 illustrated in FIGS. 6 and 7. Here, “n” is a natural number of 2 or more, and “m” is a natural number from 2 to “n” inclusive.

A nitride semiconductor device according to an aspect of the present disclosure includes a first nitride semiconductor layer with an n-type conductivity, a second nitride semiconductor layer with a p-type conductivity provided above the first nitride semiconductor layer, a source electrode in direct contact with the second nitride semiconductor layer. The nitride semiconductor device includes an active region, an inactive region surrounding the active region, and a termination region between the active region and the inactive region. The termination region is provided with two or more side walls different in an inclination angle. The two or more side walls include a first side wall and a second side wall continuous from a lower end of the first side wall. The first side wall includes an upper end located on an upper surface of the second nitride semiconductor layer, and a lower end located in the second nitride semiconductor layer. The second side wall includes a lower end reaching the first nitride semiconductor layer. The nitride semiconductor device may include the first side wall and the second side wall each of which has a taper angle decreasing continuously. An example of the first side wall is side wall 31 in each exemplary embodiment and an example of the second side wall is side wall 34 in each exemplary embodiment. That is, a height of the first side wall corresponds to mesa depth Dm1 in each exemplary embodiment, and a height of the second side wall corresponds to mesa depth Dm2 in each exemplary embodiment.

Then, the nitride semiconductor device according to each exemplary embodiment may include a vertical diode in addition to the vertical FET or instead of the vertical FET, for example. This configuration allows a forward current to flow between an anode electrode and a cathode electrode in active region 10, the anode electrode being electrically connected to second nitride semiconductor layer 22 of the p-type, and the cathode electrode being electrically connected to first nitride semiconductor layer 21 of the n-type. Source electrode 23 and the anode electrode may be integrated, or drain electrode 24 and the cathode electrode may be integrated. Then, the nitride semiconductor device according to each exemplary embodiment may include a lateral FET or a lateral diode instead of the vertical FET or the vertical diode, or in addition to the vertical FET or the vertical diode, for example. The nitride semiconductor device may include an element other than the FET or the diode.

For each of the exemplary embodiments described above, various changes, replacements, additions, omissions, and the like can be made within the scope of claims or equivalents thereof.

The present disclosure enables providing a nitride semiconductor device capable of increasing withstand voltage.

The nitride semiconductor device according to the present disclosure can be used as a power device used in a power supply circuit, an inverter circuit, or the like of an electric device, for example.

What is claimed is:

1. A nitride semiconductor device comprising:
a first nitride semiconductor layer with an n-type conductivity;
a second nitride semiconductor layer with a p-type conductivity disposed above the first nitride semiconductor layer;
a source electrode in direct contact with the second nitride semiconductor layer; and
a mesa structure with two or more steps disposed in a termination region between an active region of the nitride semiconductor device and an inactive region surrounding the active region,
wherein the mesa structure includes a mesa at a first step in which a lower end of a side wall of the mesa is located in the second nitride semiconductor layer, and each of mesas at a second and subsequent steps in which a lower end of a side wall of the mesa reaches the first nitride semiconductor layer, and
the mesa at the first step has a depth that is half or more of a film thickness of the second nitride semiconductor layer.

2. The nitride semiconductor device according to claim 1, wherein the mesa at the first step has a depth that is ⅔ or more of the film thickness of the second nitride semiconductor layer.

3. The nitride semiconductor device according to claim 1, wherein the second nitride semiconductor layer is a current block layer between a source and a drain.

4. The nitride semiconductor device according to claim 1, wherein the second nitride semiconductor layer has a p-type dopant concentration less than or equal to 5×10¹⁹ cm⁻³.

5. The nitride semiconductor device according to claim 1, wherein the mesa at the first step has a shallower depth than the mesas at the second step.

6. The nitride semiconductor device according to claim 1, wherein the mesa at the first step includes a bottom surface with a length less than or equal to 10 μm.

7. The nitride semiconductor device according to claim 1, wherein the mesa structure includes a mesa on an outermost periphery, the mesa including a side wall having a forward tapered shape.

8. The nitride semiconductor device according to claim 7, wherein the side wall of the mesa on the outermost periphery has a taper angle less than or equal to 35 degrees.

9. The nitride semiconductor device according to claim 8, wherein the side wall of the mesa on the outermost periphery has a taper angle more than or equal to 10 degrees.

10. The nitride semiconductor device according to claim 7, wherein the side wall of the mesa on the outermost periphery has a taper angle more than or equal to 50 degrees.

11. The nitride semiconductor device according to claim 1, wherein the side walls of the mesas at the first step and the second step in the mesa structure are continuously connected to each other.

12. The nitride semiconductor device according to claim 1, wherein each of the side walls at the first step and the second step in the mesa structure has a taper angle continuously decreasing.
